(19) United States
(12) Patent Application Publication
(10) Pub. No.: US 2007/0215975 A1
(43) Pub. Date: Sep. 20, 2007

(54) Method of fabricating semiconductor device

(75) Inventors: Naoki Idani, Kawasaki (JP); Satoshi Inagaki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/511,406

(22) Filed: Aug. 29, 2006

(30) Foreign Application Priority Data
Mar. 20, 2006 (JP) 2006-077518

(51) Int. Cl. H01L 23/58; H01L 21/762

(52) U.S. Cl. 257/510; 438/435; 438/424; 257/635

(57) ABSTRACT

Aiming at obtaining stable and uniform element isolation characteristics without forming the oxide film liner or the like on the inner wall surface of the isolation trench, and ensuring a sufficient level of adhesiveness of the insulating material filled in the isolation trench, and obtaining uniform and excellent element isolation characteristics and a sufficient level of adhesiveness of the buried insulating material, even when applied to large-diameter semiconductor substrates, a thermal oxide film is formed on the inner wall surface of isolation trenches, and a silicon semiconductor substrate is then annealed using a lamp annealer at a temperature higher than in the process of forming thermal oxide film, typically at 950° C. for a predetermined short time (30 seconds herein, for example), wherein the annealing modifies at least the surficial portion of thermal oxide film to have a further complete and uniform state of oxidation.

### CROSS-REFERENCE TO RELATED APPLICATIONS

This application is based upon and claims the benefit of priority from the prior Japanese Patent Application No. 2006-077518, filed on Mar. 20, 2006, the entire contents of which are incorporated herein by reference.

### BACKGROUND OF THE INVENTION

1. Field of the Invention

The present invention relates to a method of fabricating a semiconductor device having, as being formed in a device isolation region of the semiconductor substrate, a trench filled with at least an insulating material.

2. Description of the Related Art

Demands on further micronization and larger integration of semiconductor devices have been increasing in recent years, and in view of fulfilling the demands, the STI (shallow trench isolation) technique, by which trenches are formed in a device isolation region of the semiconductor substrate, and the trenches are then filled with an insulating material to thereby form an element isolation structure, has been in the mainstream of the element isolation technique specifying an element active region on the semiconductor substrate.

In further detail, in the STI technique, first isolation trenches are formed in the device isolation region, using a nitride film formed on the semiconductor substrate as a mask pattern. Next, a process step of oxidizing the inner wall surface of the isolation trenches is carried out, the isolation trenches are then filled with an HDP (High Density Plasma) assisted insulating material (HDP-SiO, for example) using the CVD (chemical vapor deposition) process assisted by a high density plasma, and the element active region is zoned by the CMP (chemical mechanical polishing) process.

The process step of oxidizing the inner wall surface of the isolation trenches after formation of the isolation trenches is aimed at preventing current leakage, because the element isolation structure formed by directly filling the HDP-assisted insulating material in the isolation trench-as-formed is causative of current leakage between the semiconductor elements.

Still another technique having been adopted in recent years, aiming at reducing the drain-off current which tends to increase as thermal stress applied to the device isolation region increases, is such as thermally oxidizing the inner wall surface of the isolation trenches, and as forming a thin nitride film (nitride film liner) (see Patent Documents 1, 2).

The related arts are disclosed in:

Japanese Patent Application Laid-Open No. 2000-208609; and

U.S. Pat. No. 5,447,884.

In recent years, and in particular in the node under a design rule of 130 nm and thereafter, large-diameter wafers called 300-nm wafers have been becoming more popular. Fabrication of semiconductor devices on the 300-nm wafers, however, raises a problem of degraded in-plane uniformity or various films formed thereon, due to their large diameter.

Also the STI technique cannot exempt from influences caused by the degraded uniformity ascribable to the increased diameter, and in particular in the process of forming the insulating film for filling the trenches, non-uniformity in a plasma used for growth of the film may occur, and the non-conformity results in etching-off of a nitride film liner preliminarily grown for stress control on the inner wall surface of the isolation trenches at around the center of the semiconductor substrate where a relatively strong plasma is applied, and consequently causes variation in element isolation characteristics.

As a solution for this problem, one possible technique may be such as forming an oxide film liner by the general CVD process so as to cover the nitride film liner. However, the solution applied to products on the node under a design rule of, for example, 90 nm or thereafter will have an extremely small size of opening of the isolation trenches. As a consequence, the insulating film filled in the isolation trenches will generate voids therein, and will fail in thoroughly filling the isolation trenches.

Even for the case where the nitride film liner is not grown, a problem arises in that in-plane variation in the adhesiveness of the insulating film for filling may occur, and this may result in separation of the insulating film at sites showing degraded adhesiveness, and may interfere thorough filling. In this case, it is supposed that non-uniformity in thermal oxide film formed on the inner wall surface of the isolation trench varies the adhesiveness of the insulating film for filling, and that the insulating film causes separation at sites where the adhesiveness was varied or degraded.

As a solution of the above-described problem, one possible measure is such as forming an oxide film liner so as to cover thermal oxide film by the general CVD process. However, also this measure raises a problem of extremely small opening of the isolation trenches similarly to as described in the above, and poor filling of the isolation trench.

### SUMMARY OF THE INVENTION

The present invention was conceived after considering the above-described situation, and is aimed at providing a method of fabricating a semiconductor device, making it possible to obtain stable and uniform element isolation characteristics without forming the oxide film liner or the like on the inner wall surface of the isolation trench, and to ensure a sufficient level of adhesiveness of the insulating material filled in the isolation trenches, and being capable of obtaining uniform and excellent element isolation characteristics and a sufficient level of adhesiveness of the buried insulating material, even when applied to large-diameter semiconductor substrates.

A method of fabricating a semiconductor device of the present invention includes forming a trench in a device isolation region of a semiconductor substrate; thermally oxidizing the inner wall surface of the trench; annealing the inner wall surface; and filling the trench with at least an insulating material.

Another aspect of the method of fabricating a semiconductor device of the present invention includes forming a trench in a device isolation region of a semiconductor substrate; thermally oxidizing the inner wall surface of the trench; subjecting the inner wall surface of the trench to plasma treatment; and filling the trench with at least an insulating material.

The semiconductor device of the present invention includes a semiconductor substrate; and an element isolation structure having, as being formed in a device isolation region of the semiconductor substrate, a trench filled with at least an insulating material; wherein the element isolation structure has an oxide film formed by thermal oxidation of the inner wall surface of the trench, and has a nitride film formed by thermal nitriding of the surface of the oxide film.

Another aspect of the semiconductor device of the present invention includes a semiconductor substrate; and an element isolation structure having, as formed in a device isolation region of the semiconductor substrate, a trench filled with at least an insulating material; wherein the element isolation structure has an oxide film formed by thermal oxidation of the inner wall surface of the trench, and has a nitride film formed by plasma-nitriding of the surface of the oxide film.

Another aspect of the semiconductor device of the present invention includes a semiconductor substrate; and an element isolation structure having, as formed in a device isolation region of the semiconductor substrate, a trench filled with at least an insulating material; wherein the element isolation structure has a first oxide film formed by thermal oxidation of the inner wall surface of the trench, has a nitride film covering the inner wall surface while placing the first oxide film thereunder, and has a second oxide film formed by thermal oxidation of the surface of the nitride film.

Still another aspect of the semiconductor device of the present invention includes a semiconductor substrate; and an element isolation structure having, as formed in a device isolation region of the semiconductor substrate, a trench filled with at least an insulating material; wherein the element isolation structure has a first oxide film formed by thermal oxidation of the inner wall surface of the trench, has a nitride film covering the inner wall surface while placing the first oxide film thereunder, and has a second oxide film formed by plasma oxidation of the surface of the nitride film.

### BRIEF DESCRIPTION OF THE DRAWINGS

FIGS. 1A to 1D are schematic sectional views sequentially showing process steps of fabricating a semiconductor device of a first embodiment;

FIGS. 2A to 2C are schematic sectional views sequentially showing process steps of fabricating a semiconductor device of a first embodiment;

FIGS. 3A to 3D are schematic sectional views sequentially showing process steps of fabricating a semiconductor device according to a modified example of a first embodiment;

FIGS. 4A to 4C are schematic sectional views sequentially showing process steps of fabricating a semiconductor device according to a modified example of a first embodiment;

FIGS. 5A to 5D are schematic sectional views sequentially showing process steps of fabricating a semiconductor device of a second embodiment;

FIGS. 6A to 6C are schematic sectional views sequentially showing process steps of fabricating a semiconductor device of a second embodiment;

FIGS. 7A to 7D are schematic sectional views sequentially showing process steps of fabricating a semiconductor device according to a modified example of a second embodiment;

FIGS. 8A to 8C are schematic sectional views sequentially showing process steps of fabricating a semiconductor device according to a modified example of a second embodiment;

FIGS. 9A to 9E are schematic sectional views sequentially showing process steps of fabricating a semiconductor device of a third embodiment;

FIGS. 10A to 10C are schematic sectional views sequentially showing process steps of fabricating a semiconductor device of a third embodiment;

FIGS. 11A to 11E are schematic sectional views sequentially showing process steps of fabricating a semiconductor device according to a modified example of a third embodiment;

FIGS. 12A to 12C are schematic sectional views sequentially showing process steps of fabricating a semiconductor device according to a modified example of a third embodiment;

FIGS. 13A to 13E are schematic sectional views sequentially showing process steps of fabricating a semiconductor device of a fourth embodiment;

FIGS. 14A to 14C are schematic sectional views sequentially showing process steps of fabricating a semiconductor device of a fourth embodiment;

FIGS. 15A to 15E are schematic sectional views sequentially showing process steps of fabricating a semiconductor device according to a modified example of a fourth embodiment; and

FIGS. 16A to 16C are schematic sectional views sequentially showing process steps of fabricating a semiconductor device according to a modified example of a fourth embodiment.

### DETAILED DESCRIPTION OF THE PREFERRED EMBODIMENTS

### —Basic Concept of the Present Invention—

The present inventors put a focus on a fact that non-uniform element isolation characteristics and non-uniform adhesiveness of the filled insulating material are ascribable to non-uniformity of an as-it-were frontmost film formed on the inner wall surface of the isolation trench, that is, a film directly brought into contact with the insulating material filled in the isolation trench, and conceived the present invention in view of uniformalizing the film. The frontmost film can be exemplified by thermal oxide film formed on the inner wall surface of the isolation trench for the purpose of improving the element isolation function, and nitride film liner formed on the inner wall surface of the isolation trench, while placing thermal oxide film thereunder, for the purpose of controlling stress induced by the filled insulating material.

In the present invention, under a state having thermal oxide film formed on the inner wall surface of the isolation trench, or under a state having the nitride film liner formed on the inner wall surface while placing thermal oxide film thereunder, the frontmost film formed on the inner wall surface of the isolation trench (that is, thermal oxide film or the nitride film liner) is annealed at high temperatures, or plasma-treated. By the process, the surficial portion of the frontmost film is treated to thereby create a further complete and uniform state of layer, so that the present invention can successfully obtain uniform and excellent element isolation characteristics, and uniform and a sufficient level of adhesiveness of the insulating film, even when applied to large-diameter semiconductor substrates.

More specifically, the annealing or the plasma treatment is carried out in a treatment apparatus conditioned as having an atmosphere containing oxygen gas or an oxygen-containing gas (oxygen atmosphere), or as having an atmosphere containing nitrogen gas or a nitrogen-containing gas (nitrogen atmosphere).

By the treatment under the oxygen atmosphere, the frontmost film given as thermal oxide film is modified to have a further complete and uniform state of oxidation in the surficial portion of thermal oxide film. The frontmost film given as the nitride film liner is modified to have an extra-thin oxide film (several nanometers thick or around) formed in the surficial portion of the nitride film liner, as having a complete and uniform state of oxidation.

On the other hand, by the treatment under the nitrogen atmosphere, the frontmost film given as thermal oxide film is modified to have an extra-thin nitride film (several nanometers thick or around) formed in the surficial portion of thermal oxide film, as having a complete and uniform state of nitriding. The frontmost film given as the nitride film liner is modified to have a further complete and uniform state of nitriding in the surficial portion of the nitride film liner.

### —Preferred Embodiments Applied with the Present Invention—

Paragraphs below will detail preferred embodiments applied with the present invention, referring to the attached drawings.

### First Embodiment

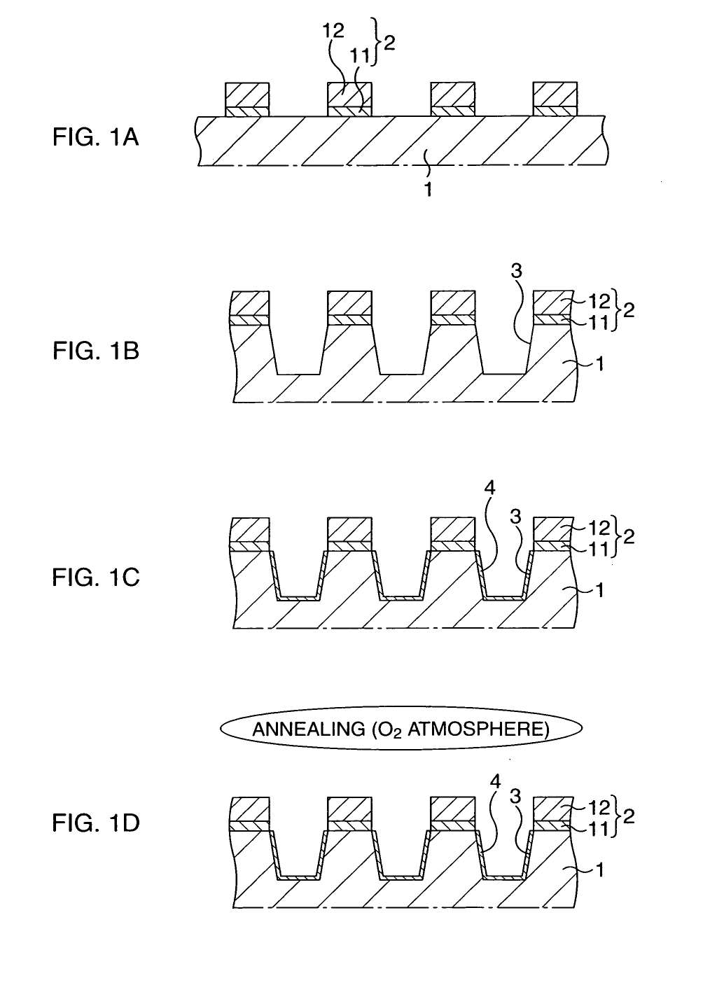

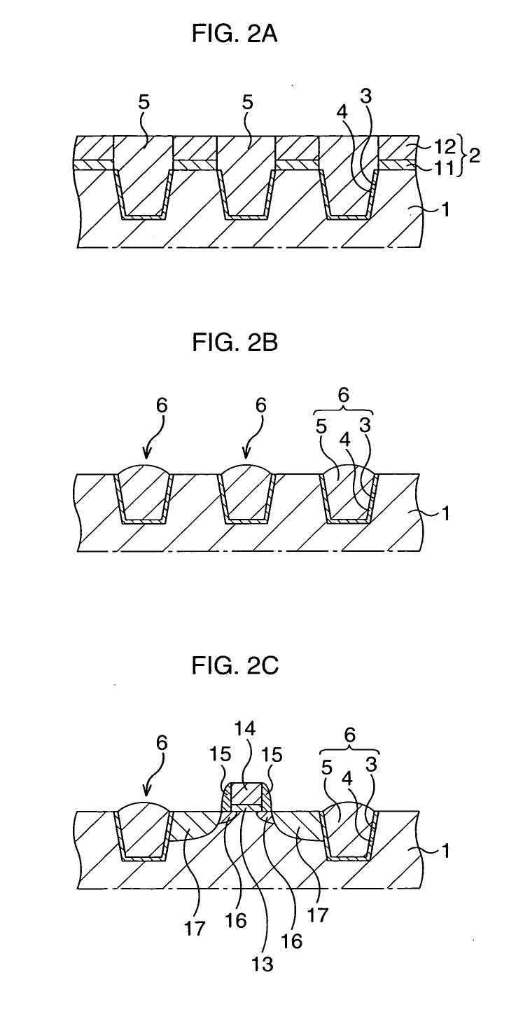

FIGS. 1A to 1D and FIGS. 2A to 2C are schematic sectional views sequentially showing a method of fabricating a semiconductor device of a first embodiment.

First, as shown in FIG. 1A, a mask pattern 2 is formed in a device isolation region of the silicon semiconductor substrate 1.

In further detail, first a silicon oxide film 11 and a silicon nitride film 12 are sequentially grown on the entire surface of the silicon semiconductor substrate 1. The silicon nitride film 12 and the silicon oxide film 11 are then patterned by lithography and dry etching, and leave them so as to expose therein only the device isolation region of the silicon semiconductor substrate 1, to thereby form a mask pattern 2.

Next, as shown in FIG. 1B, isolation trenches 3 are formed in the device isolation region of the silicon semiconductor substrate 1.

In further detail, silicon semiconductor substrate 1 is dry-etched through the mask pattern 2, to thereby form the isolation trenches 3 in the device isolation region of the silicon semiconductor substrate 1.

Next, as shown in FIG. 1C, a thermal oxide film 4 is formed on the inner wall surface of the isolation trenches 3.

In further detail, the silicon semiconductor substrate 1 is placed in a batch-type annealing furnace, oxygen gas or an oxygen-containing gas is introduced into the annealing furnace to thereby condition an oxygen atmosphere, and semiconductor substrate 1 is annealed typically at 800° C. for 30 minutes. By the annealing, thermal oxide film 4 is formed typically to as thick as 10 nm or around on the inner wall surface of the isolation trenches 3.

Next, as shown in FIG. 1D, thermal oxide film 4 is annealed at high temperatures.

In further detail, using a single-wafer-type annealer, which is a lamp annealer herein, the silicon semiconductor substrate 1 is annealed slice-by-slice. More specifically, oxygen gas or an oxygen-containing gas (a mixed gas of oxygen and a carrier gas such as argon gas) is introduced into the lamp-annealer to thereby condition an oxygen atmosphere, and the silicon semiconductor substrate 1 is annealed at a temperature higher than in the process of forming thermal oxide film 4, typically at 950° C. for a predetermined short time (30 seconds herein, for example). By the annealing, at least the surficial portion of thermal oxide film 4 is modified to have a further complete and uniform state of oxidation. In addition, the annealing using the lamp annealer can successfully remove dusts or any other residues remaining on the silicon semiconductor substrate 1 and in the isolation trenches 3, and can thereby create an extremely clean surface state of the substrate.

In this annealing, it is also allowable to use a batch-type annealing furnace similarly to as in the formation of thermal oxide film 4, in place of using the single-wafer-type annealer.

More specifically, oxygen gas or an oxygen-containing gas (a mixed gas of oxygen and a carrier gas such as argon gas) is introduced into the annealing furnace to thereby condition an oxygen atmosphere, and the silicon semiconductor substrate 1 is annealed at a temperature higher than in the process of forming thermal oxide film 4, typically at 950° C. for 30 minutes. By the annealing, at least the surficial portion of thermal oxide film 4 is modified to have a further complete and uniform state of oxidation.

Next, as shown in FIG. 2A, a buried insulating film 5 in the isolation trenches 3 is formed.

In further detail, an HDP-SiO film is deposited typically by the HDP-CVD process, so as to fill the isolation trenches 3 while placing thermal oxide film 4 thereunder, to thereby form the buried insulating film 5. The surficial portion of the buried insulating film 5 is then polished by the CMP process, using the mask pattern 2 as a polishing stopper.

Next, as shown in FIG. 2B, element isolation structures 6 are formed.

In further detail, the nitride film 12 of the mask pattern 2 is isotropically etched typically using phosphoric acid (H₃PO₄) as an etching solution, to thereby remove the nitride film 12. The oxide film 11 of the mask pattern 2 is then isotropically etched using hydrofluoric acid (HF) as an etching solution, to thereby remove the oxide film 11. By these processes, the element isolation structures 6 are formed as having HDP-SiO filled in the isolation trenches 3 while placing thermal oxide film thereunder, and as zoning the element active region on the silicon semiconductor substrate 1.

Next, as shown in FIG. 2C, a MOS transistor 10 is formed in the element active regions zoned by the element isolation structures 6.

The semiconductor element herein is exemplified by the MOS transistor 10. The MOS transistor 10 has a gate electrode 14 patterned in the element active regions while placing a thin gate insulating film 13 placed thereunder, and has sidewall insulating films 15 on both side faces of the gate electrode 14. The element active regions have, in the surficial portions thereof on both sides of the gate electrode 14, LDD regions formed by ion implantation of an impurity as being aligned with the sidewall insulating films 15, and source/drain regions 17 formed by ion implantation of an impurity as being aligned with the gate electrode 14 and as partially overlapping the LDD regions 16. The impurities used herein for the LDD regions 16 and the source/drain regions 17 may be phosphorus (P⁺) or arsenic (As⁺) for the MOS transistor 10 of n-type, and may be boron (B⁺) for p-type.

Thereafter, an interlayer insulating film, and various interconnections (not shown) connected to the source/drain regions 17 and so forth are formed, to thereby complete the MOS transistor 10.

As has been described in the above, this embodiment can ensure a sufficient level of adhesiveness of the buried insulating film 5 filled in the isolation trenches 3, and can prevent the buried insulating film 5 from separating from the isolation trenches 3, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring uniform and a sufficient level of adhesiveness of the buried insulating film 5, even when applied to large-diameter semiconductor substrates.

### Modified Example

Paragraphs below will explain a modified example of the first embodiment. This example involves annealing of thermal oxide film 4 similar to as in the first embodiment, but differs from the first embodiment in the atmosphere of the annealing. It is to be noted that any constituents in this embodiment commonly appear in the first embodiment will be given with the same reference numerals, in order to avoid repetitive detailed explanation.

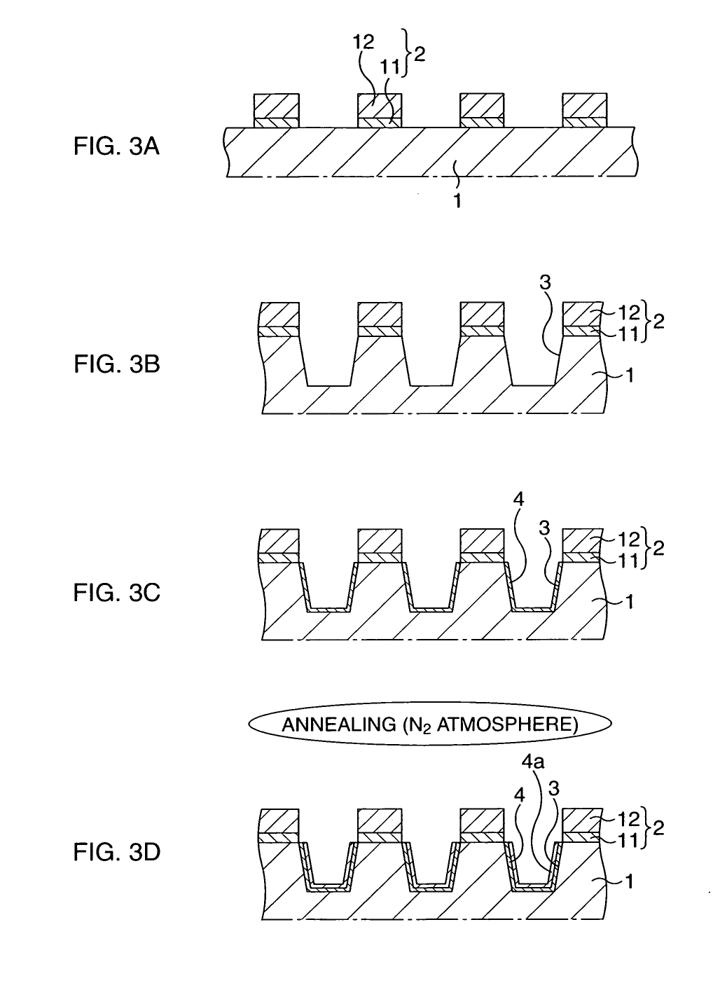

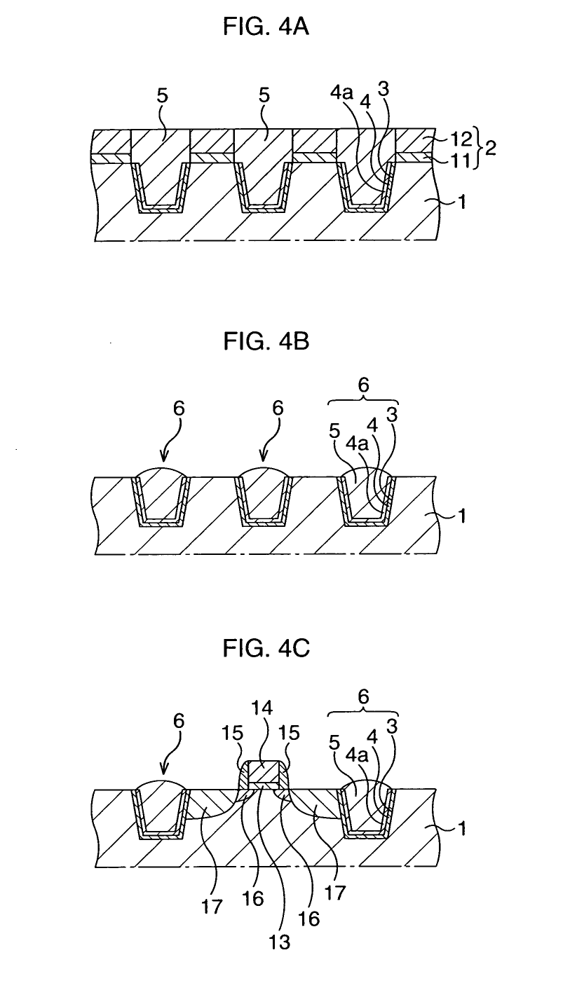

FIGS. 3A to 3D and FIGS. 4A to 4C are schematic sectional views sequentially showing process steps of fabricating a semiconductor device according to a modified example of the first embodiment.

First, as shown in FIGS. 3A to 3C, thermal oxide film 4 is formed on the inner wall surface of the isolation trenches 3, by the processes similar to those shown in FIGS. 1A to 1C in the first embodiment.

Next, as shown in FIG. 3D, thermal oxide film 4 is annealed at high temperatures.

In further detail, using a single-wafer-type annealer, which is a lamp annealer herein, the silicon semiconductor substrate 1 is annealed slice-by-slice. More specifically, nitrogen gas or a nitrogen-containing gas (a mixed gas of nitrogen and a carrier gas such as argon gas) is introduced into the lamp annealer to thereby condition a nitrogen atmosphere, and the silicon semiconductor substrate 1 is annealed at a temperature higher than in the process of forming thermal oxide film 4, typically at 950° C. for a predetermined short time (30 seconds herein, for example). By the annealing, an extra-thin (several nanometers thick, and 3 nm or around herein) thermal nitride film 4a having a complete and uniform state of nitriding is formed in at least the surficial portion of thermal oxide film 4. In addition, the annealing using the lamp annealer can successfully remove dusts or any other residues remaining on the silicon semiconductor substrate 1 and in the isolation trenches 3, and can thereby create an extremely clean surface state of the substrate.

In this annealing, it is also allowable to use a batch-type annealing furnace similarly to as in the formation of thermal oxide film 4, in place of using the single-wafer-type annealer.

More specifically, nitrogen gas or a nitrogen-containing gas (a mixed gas of nitrogen and a carrier gas such as argon gas) is introduced into the annealing furnace to thereby condition a nitrogen atmosphere, and the silicon semiconductor substrate 1 is annealed at a temperature higher than in the process of forming thermal oxide film 4, typically at 950° C. for 30 minutes. By the annealing, a thermal nitride film 4a having a complete and uniform state of nitriding is formed in at least the surficial portion of thermal oxide film 4.

Thereafter, as shown in FIGS. 4A to 4C, by the process steps similar to those shown in FIGS. 2A to 2C in the first embodiment, a semiconductor device is completed as having the element active regions zoned by the element isolation structures 6 on the silicon semiconductor substrate 1, and as having the MOS transistor 10 formed in the element active region.

As has been described in the above, this embodiment can ensure a sufficient level of adhesiveness of the buried insulating film 5 filled in the isolation trenches 3, and can prevent the buried insulating film 5 from separating from the isolation trenches 3, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring uniform and a sufficient level of adhesiveness of the buried insulating film 5, even when applied to large-diameter semiconductor substrates.

### Second Embodiment

Paragraphs below will explain a second embodiment of the present invention. This embodiment differs from the first embodiment in that thermal oxide film 4 is subjected to plasma treatment, in place of annealing. It is to be noted that any constituents in this embodiment commonly appear in the first embodiment will be given with the same reference numerals, in order to avoid repetitive detailed explanation.

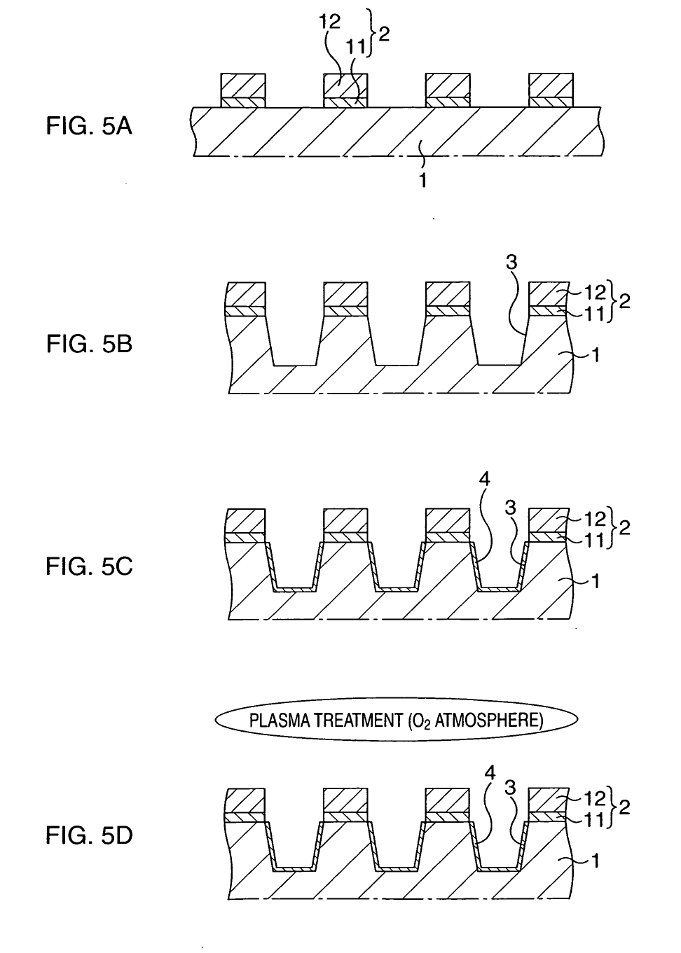

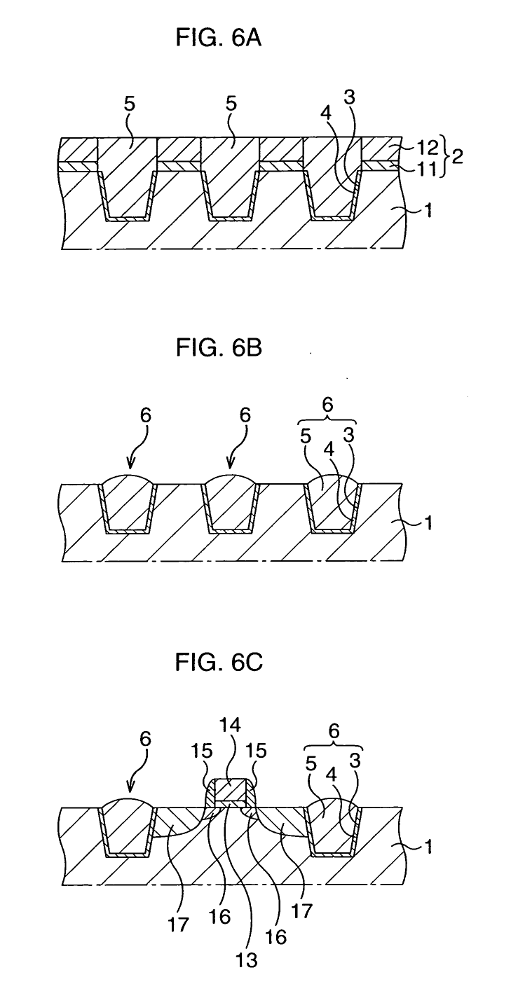

FIGS. 5A to 5D and FIGS. 6A to 6C are schematic sectional views sequentially showing process steps of fabricating a semiconductor device according to the second embodiment.

First, as shown in FIGS. 5A to 5C, thermal oxide film 4 is formed on the inner wall surface of the isolation trenches 3, by the processes similar to those shown in FIGS. 1A to 1C in the first embodiment.

Next, as shown in FIG. 5D, thermal oxide film 4 is subjected to plasma treatment.

In further detail, using a plasma treatment apparatus, oxygen gas or an oxygen-containing gas (a mixed gas of oxygen and a carrier gas such as argon gas) is introduced therein, so as to condition an oxygen atmosphere as having a pressure of 1.3×10³ Pa (10 Torr), a plasma is then excited therein typically at 400° C., and thermal oxide film 4 is exposed to the plasma. By the plasma treatment, at least the surficial portion of thermal oxide film 4 is modified to have a further complete and uniform state of oxidation.

Thereafter, as shown in FIGS. 6A to 6C, by the process steps similar to those shown in FIGS. 2A to 2C in the first embodiment, a semiconductor device is completed as having the element active regions zoned by the element isolation structures 6 on the silicon semiconductor substrate 1, and as having the MOS transistor 10 formed in the element active region.

As has been described in the above, this embodiment can ensure a sufficient level of adhesiveness of the buried insulating film 5 filled in the isolation trenches 3, and can prevent the buried insulating film 5 from separating from the isolation trenches 3, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring uniform and a sufficient level of adhesiveness of the buried insulating film 5, even when applied to large-diameter semiconductor substrates.

### Modified Example

Paragraphs below will explain a modified example of the second embodiment. This example involves plasma treatment of thermal oxide film 4 similar to as in the second embodiment, but differs from the second embodiment in the atmosphere of the plasma treatment. It is to be noted that any constituents in this embodiment commonly appear in the second embodiment will be given with the same reference numerals, in order to avoid repetitive explanation.

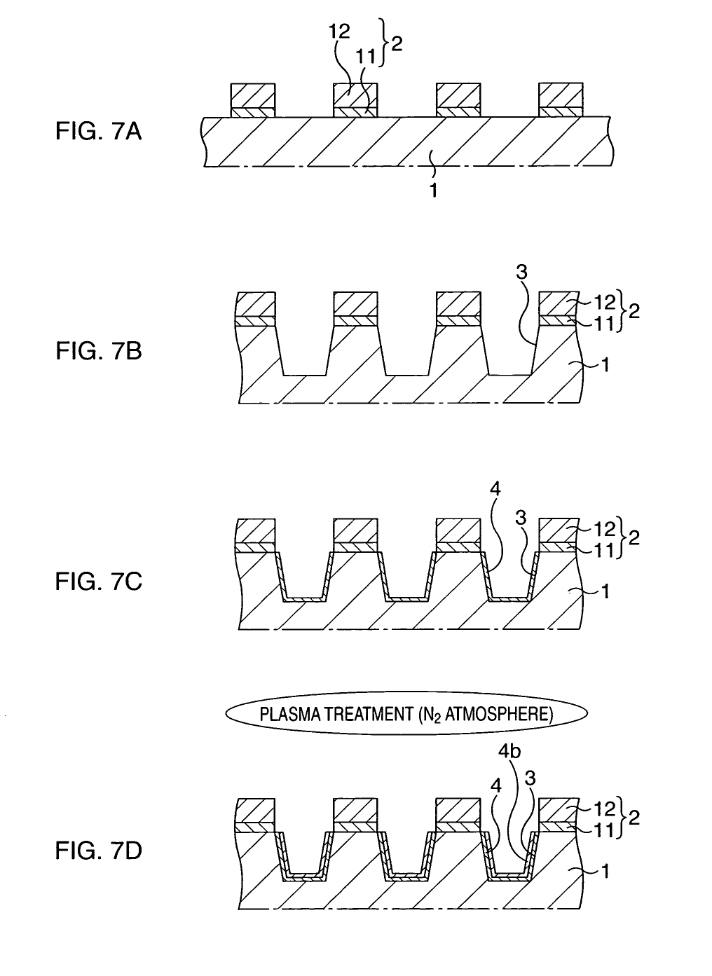

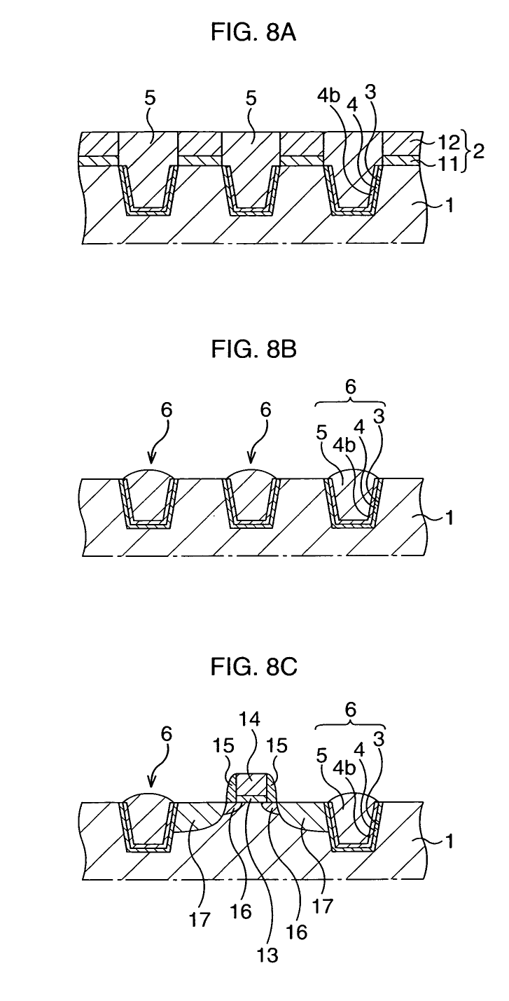

FIGS. 7A to 7D and FIGS. 8A to 8C are schematic sectional views sequentially showing process steps of fabricating a semiconductor device according to a modified example of the second embodiment.

First, as shown in FIGS. 7A to 7C, thermal oxide film 4 is formed on the inner wall surface of the isolation trenches 3, by the processes similar to those shown in FIGS. 5A to 5C in the second embodiment.

Next, as shown in FIG. 7D, thermal oxide film 4 is subjected to plasma treatment.

In further detail, using a plasma treatment apparatus, nitrogen gas or a nitrogen-containing gas (a mixed gas of nitrogen and a carrier gas such as argon gas) is introduced therein, so as to condition a nitrogen atmosphere as having a pressure of 1.3×10³ Pa (10 Torr), a plasma is then excited therein typically at 400° C., and thermal oxide film 4 is exposed to the plasma. By the plasma treatment, an extra-thin (several nanometers thick, and 3 nm or around herein) thermal nitride film 4b having a complete and uniform state of nitriding is formed in at least the surficial portion of thermal oxide film 4.

Thereafter, as shown in FIGS. 8A to 8C, by the process steps similar to those shown in FIGS. 6A to 6C in the second embodiment, a semiconductor device is completed as having the element active regions zoned by the element isolation structures 6 on the silicon semiconductor substrate 1, and as having the MOS transistor 10 formed in the element active region.

As has been described in the above, this embodiment can ensure a sufficient level of adhesiveness of the buried insulating film 5 filled in the isolation trenches 3, and can prevent the buried insulating film 5 from separating from the isolation trenches 3, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring uniform and a sufficient level of adhesiveness of the buried insulating film 5, even when applied to large-diameter semiconductor substrates.

### Third Embodiment

Paragraphs below will explain a third embodiment of the present invention. This embodiment differs from the first embodiment in that a nitride film liner is additionally formed. It is to be noted that any constituents in this embodiment commonly appear in the first embodiment will be given with the same reference numerals, in order to avoid repetitive detailed explanation.

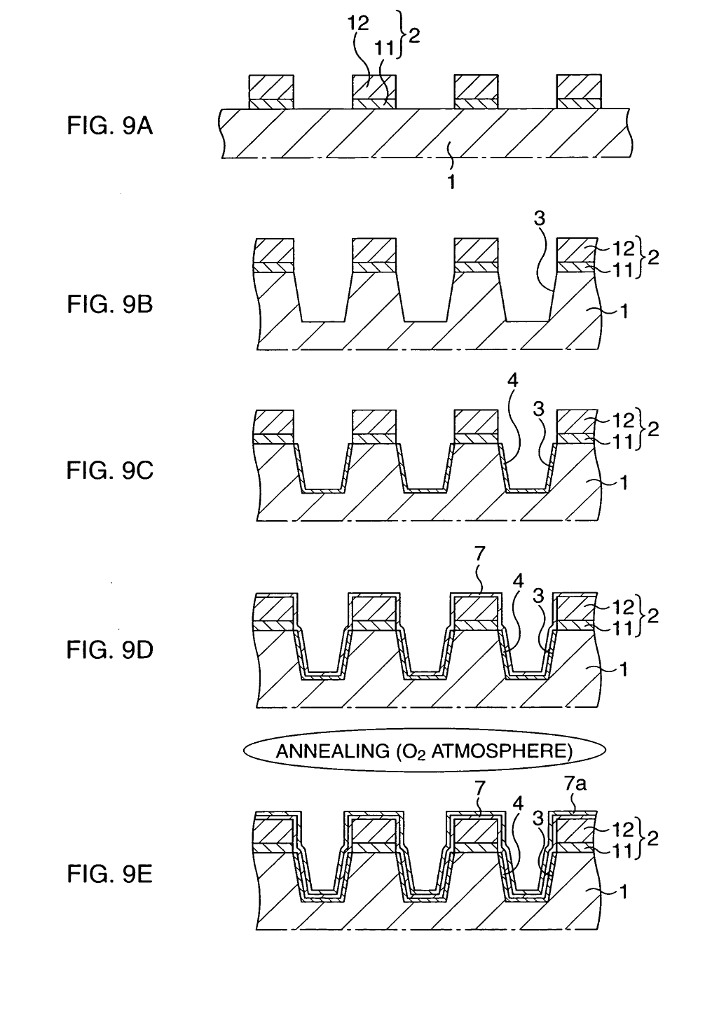

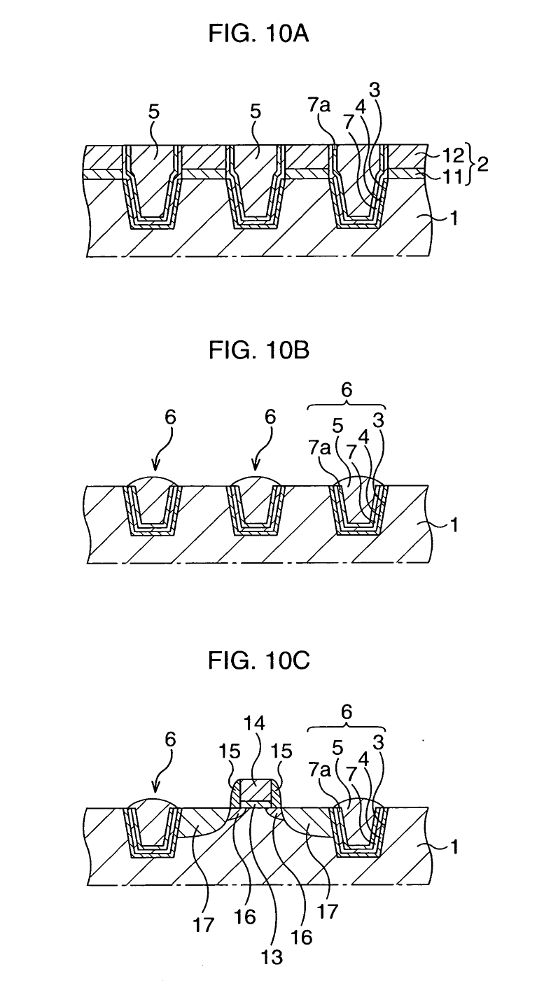

FIGS. 9A to 9E and FIGS. 10A to 10C are schematic sectional views sequentially showing process steps of fabricating a semiconductor device according to the third embodiment.

First, as shown in FIGS. 9A to 9C, thermal oxide film 4 is formed on the inner wall surface of the isolation trenches 3, by the processes similar to those shown in FIGS. 1A to 1C in the first embodiment.

Next, as shown in FIG. 9D, a nitride film liner 7 is formed so as to cover thermal oxide film 4.

In further detail, a silicon nitride film is deposited typically by the CVD process, so as to cover thermal oxide film 4, or so as to cover the inner wall surface of the isolation trenches 3 while placing thermal oxide film 4 thereunder, to as thick as 5 nm or around, to thereby form the nitride film liner 7.

Next, as shown in FIG. 9E, thermal oxide film 4 is annealed at high temperatures.

In further detail, using a single-wafer-type annealer, which is a lamp annealer herein, the silicon semiconductor substrate 1 is annealed slice-by-slice. More specifically, oxygen gas or an oxygen-containing gas (a mixed gas of oxygen and a carrier gas such as argon gas) is introduced into the lamp annealer to thereby condition an oxygen atmosphere, and the silicon semiconductor substrate 1 is annealed at a temperature higher than in the process of forming thermal oxide film 4, typically at 900° C. for a predetermined short time (30 seconds herein, for example). By the annealing, an extra-thin (several nanometers thick, and 3 nm or around herein) thermal oxide film 7a having a complete and uniform state of oxidation is formed in at least the surficial portion of the nitride film liner 7. In addition, the annealing using the lamp annealer can successfully remove dusts or any other residues remaining on the silicon semiconductor substrate 1 and in the isolation trenches 3, and can thereby create an extremely clean surface state of the substrate.

In this annealing, it is also allowable to use a batch-type annealing furnace similarly to as in the formation of thermal oxide film 4, in place of using the single-wafer-type annealer.

More specifically, oxygen gas or an oxygen-containing gas (a mixed gas of oxygen and a carrier gas such as argon gas) is introduced into the annealing furnace to thereby condition an oxygen atmosphere, and the silicon semiconductor substrate 1 is annealed at a temperature higher than in the process of forming thermal oxide film 4, typically at 900° C. for 30 minutes. By the annealing, a thermal oxide film 7a having a complete and uniform state of oxidation is formed in at least the surficial portion of the nitride film liner 7.

Thereafter, as shown in FIGS. 10A to 10C, by the process steps similar to those shown in FIGS. 2A to 2C in the first embodiment, a semiconductor device is completed as having the element active regions zoned by the element isolation structures 6 on the silicon semiconductor substrate 1, and as having the MOS transistor 10 formed in the element active region.

In the process of filling the isolation trenches 3 with the buried insulating film 5 shown in FIG. 10B, deposition of the HDP-SiO film on the nitride film liner 7, without being annealed as in the conventional process, results in etching of the nitride film liner 7 at the center portion of the silicon semiconductor substrate 1, due to a plasma excited for growth of the HDP-SiO film.

In contrast in this embodiment, the nitride film liner 7 has, in the surficial portion thereof, thermal oxide film 7a having a complete and uniform state of oxidation, so that thermal oxide film 7a can function as an etching protecting film, and thereby etching of the nitride film liner 7 is avoidable. Moreover, thermal oxide film 7a is formed with an extra thinness by thermal oxidation, so that size of the opening of the isolation trenches 3 is kept almost unchanged, raising no fear of narrowing of the opening.

As has been described in the above, this embodiment can prevent the nitride film liner 7 from being unnecessarily etched off during formation of the buried insulating film 5, and can obtain stable and uniform element isolation characteristics, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring excellent element isolation characteristics, even when applied to large-diameter semiconductor substrates.

### Modified Example

Paragraphs below will explain a modified example of the third embodiment. This example involves annealing of the nitride film liner 7 similar to as in the third embodiment, but differs from the third embodiment in the atmosphere of the annealing. It is to be noted that any constituents in this embodiment commonly appear in the third embodiment will be given with the same reference numerals, in order to avoid repetitive detailed explanation.

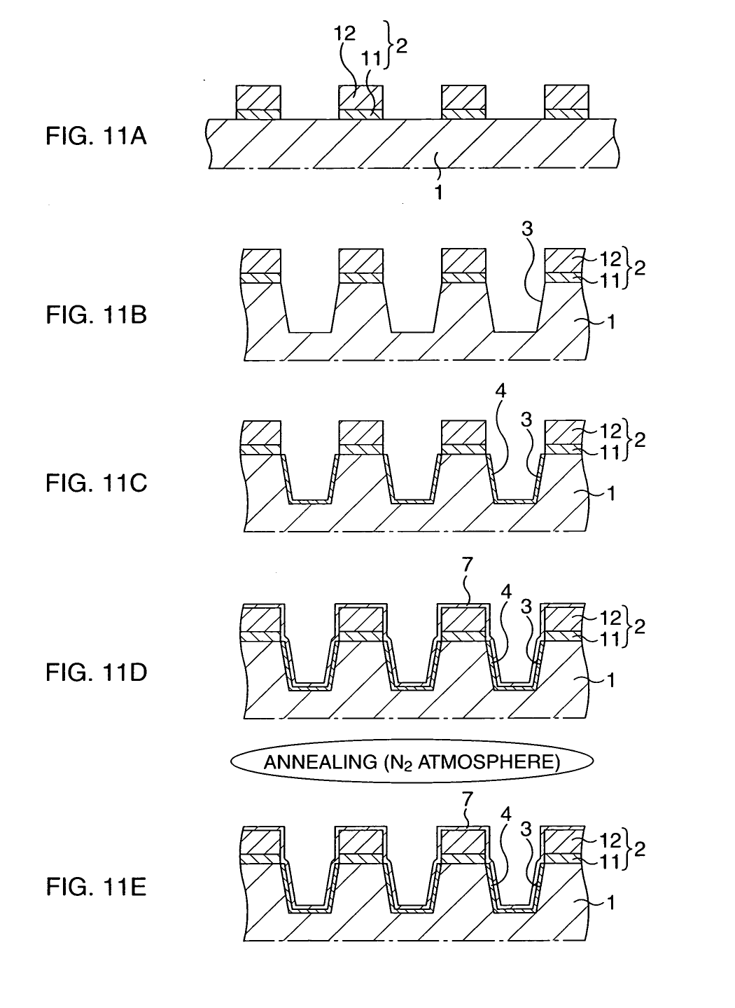

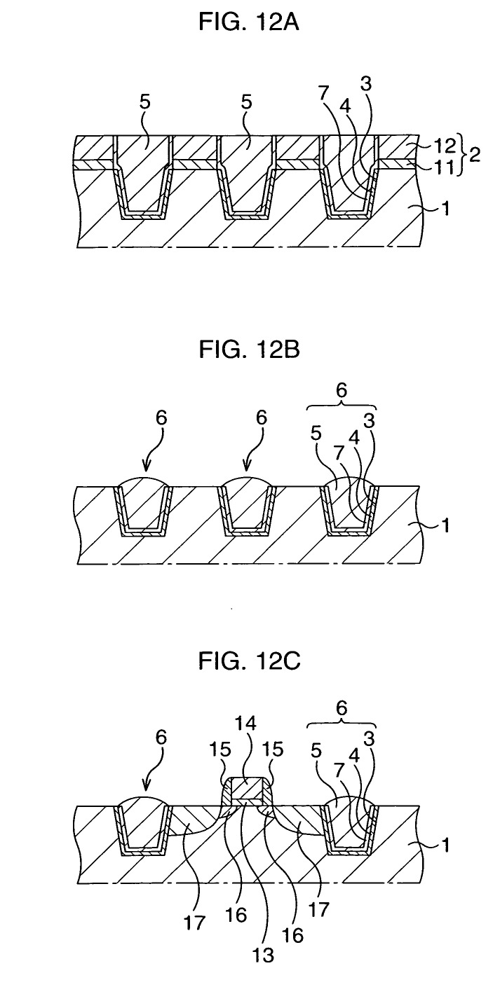

FIGS. 11A to 11E and FIGS. 12A to 12C are schematic sectional views sequentially showing process steps of fabricating a semiconductor device according to a modified example of the third embodiment.

First, as shown in FIGS. 11A to 11D, the nitride film liner 7 is formed on the inner wall surface of the isolation trenches 3 while placing thermal oxide film 4 thereunder, by the processes similar to those shown in FIGS. 9A to 9D in the third embodiment.

Next, as shown in FIG. 11E, the nitride film liner 7 is annealed at high temperatures.

In further detail, using a single-wafer-type annealer, which is a lamp annealer herein, the silicon semiconductor substrate 1 is annealed slice-by-slice. More specifically, nitrogen gas or a nitrogen-containing gas (a mixed gas of nitrogen and a carrier gas such as argon gas) is introduced into the lamp annealer to thereby condition a nitrogen atmosphere, and the silicon semiconductor substrate 1 is annealed at a temperature higher than in the process of forming thermal oxide film 4, typically at 900° C. for a predetermined short time (30 seconds herein, for example). By the annealing, at least the surficial portion of the nitride film liner 7 is modified to have a further complete and uniform state of nitriding. In addition, the annealing using the lamp annealer can successfully remove dusts or any other residues remaining on the silicon semiconductor substrate 1 and in the isolation trenches 3, and can thereby create an extremely clean surface state of the substrate.

In this annealing, it is also allowable to use a batch-type annealing furnace similarly to as in the formation of thermal oxide film 4, in place of using the single-wafer-type annealer.

More specifically, nitrogen gas or a nitrogen-containing gas (a mixed gas of nitrogen and a carrier gas such as argon gas) is introduced into the annealing furnace to thereby condition a nitrogen atmosphere, and the silicon semiconductor substrate 1 is annealed at a temperature higher than in the process of forming thermal oxide film 4, typically at 900° C. for 30 minutes. By the annealing, at least the surficial portion of the nitride film liner 7 is modified to have a further complete and uniform state of nitriding.

Thereafter, as shown in FIGS. 12A to 12C, by the process steps similar to those shown in FIGS. 10A to 10C in the third embodiment, a semiconductor device is completed as having the element active regions zoned by the element isolation structures 6 on the silicon semiconductor substrate 1, and as having the MOS transistor 10 formed in the element active region.

In the process of filling the isolation trenches 3 with the buried insulating film 5 shown in FIG. 12B, deposition of the HDP-SiO film on the nitride film liner 7, without being annealed as in the conventional process, results in etching of the nitride film liner 7 at the center portion of the silicon semiconductor substrate 1, due to a plasma excited for growth of the HDP-SiO film.

In contrast in this embodiment, the surficial portion of the nitride film liner 7 is modified to have a further complete and uniform state of nitriding, so that the surficial portion can function as an etching protecting film, and thereby etching of the nitride film liner 7 is avoidable. Moreover, the surficial portion is composed of the nitride film liner 7 further completely nitrided, so that size of the opening of the isolation trenches 3 is kept almost unchanged, raising no fear of narrowing of the opening.

As has been described in the above, this embodiment can prevent the nitride film liner 7 from being unnecessarily etched off during formation of the buried insulating film 5, and can obtain stable and uniform element isolation characteristics, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring excellent element isolation characteristics, even when applied to large-diameter semiconductor substrates.

### Fourth Embodiment

Paragraphs below will explain a fourth embodiment of the present invention. This embodiment differs from the third embodiment in that the nitride film liner 7 is subjected to plasma treatment, in place of annealing. It is to be noted that any constituents in this embodiment commonly appear in the second embodiment will be given with the same reference numerals, in order to avoid repetitive explanation.

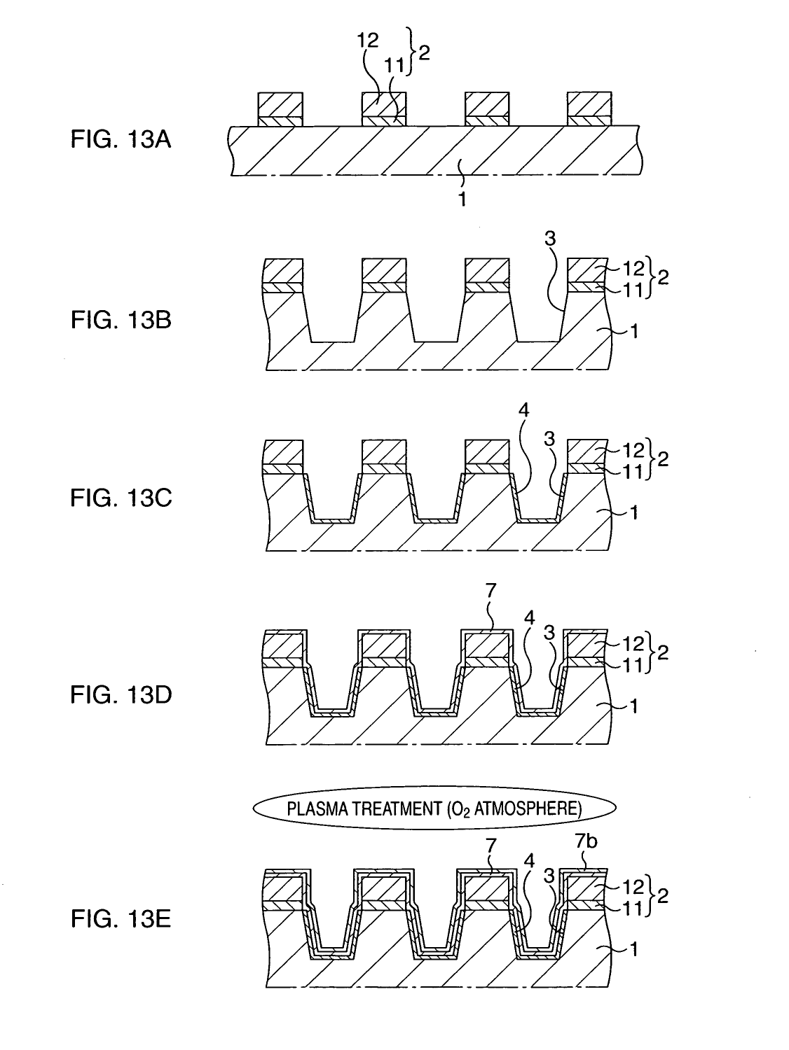

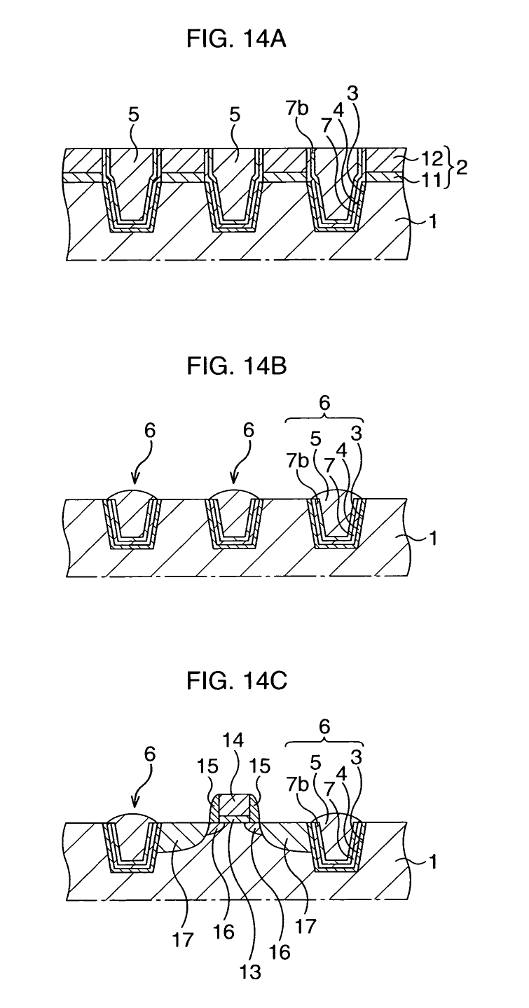

FIGS. 13A to 13E and FIGS. 14A to 14C are schematic sectional views sequentially showing process steps of fabricating a semiconductor device according to the fourth embodiment.

First, as shown in FIGS. 13A to 13D, the nitride film liner 7 is formed on the inner wall surface of the isolation trenches 3 while placing thermal oxide film 4 thereunder, by the processes similar to those shown in FIGS. 9A to 9D in the third embodiment.

Next, as shown in FIG. 13E, the nitride film liner 7 is subjected to plasma treatment.

In further detail, using a plasma treatment apparatus, oxygen gas or an oxygen-containing gas (a mixed gas of oxygen and a carrier gas such as argon gas) is introduced therein, so as to condition an oxygen atmosphere as having a pressure of 667 Pa (5 Torr), a plasma is then excited therein typically at 400° C., and the nitride film liner 7 is exposed to the plasma. By the plasma treatment, an extra-thin (several nanometers thick, and 2 nm or around herein) plasma-assisted oxide film 7b having a complete and uniform state of oxidation is formed in at least the surficial portion of the nitride film liner 7.

Thereafter, as shown in FIGS. 14A to 14C, by the process steps similar to those shown in FIGS. 10A to 10C in the third embodiment, a semiconductor device is completed as having the element active regions zoned by the element isolation structures 6 on the silicon semiconductor substrate 1, and as having the MOS transistor 10 formed in the element active region.

In the process of filling the isolation trenches 3 with the buried insulating film 5 shown in FIG. 14B, deposition of the HDP-SiO film on the nitride film liner 7, without being annealed as in the conventional process, results in etching of the nitride film liner 7 at the center portion of the silicon semiconductor substrate 1, due to a plasma excited for growth of the HDP-SiO film.

In contrast in this embodiment, the nitride film liner 7 has, in the surficial portion thereof, the plasma-assisted oxide film 7b having a complete and uniform state of oxidation, so that the plasma-assisted oxide film 7b can function as an etching protecting film, and thereby etching of the nitride film liner 7 is avoidable. Moreover, the plasma-assisted oxide film 7a is formed with an extra thinness, so that size of the opening of the isolation trenches 3 is kept almost unchanged, raising no fear of narrowing of the opening.

As has been described in the above, this embodiment can prevent the nitride film liner 7 from being unnecessarily etched off during formation of the buried insulating film 5, and can obtain stable and uniform element isolation characteristics, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring excellent element isolation characteristics, even when applied to large-diameter semiconductor substrates.

### Modified Example

Paragraphs below will explain a modified example of the fourth embodiment. This example involves plasma treatment of the nitride film liner 7 similar to as in the fourth embodiment, but differs from the fourth embodiment in the atmosphere of the plasma treatment. It is to be noted that any constituents in this embodiment commonly appear in the fourth embodiment will be given with the same reference numerals, in order to avoid repetitive detailed explanation.

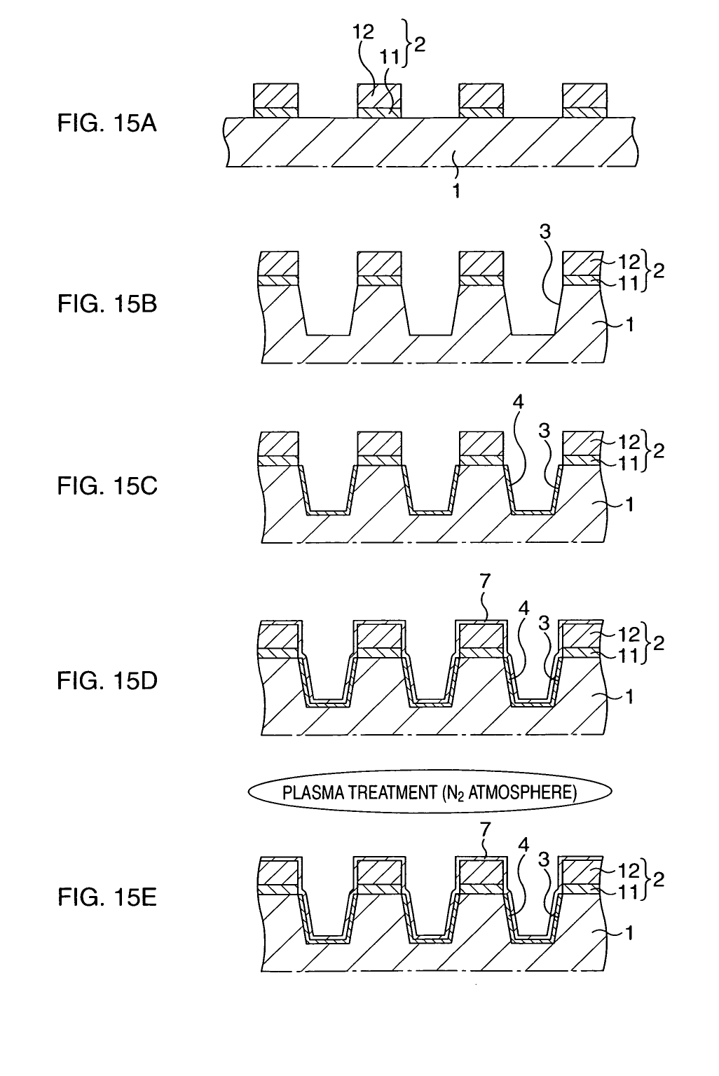

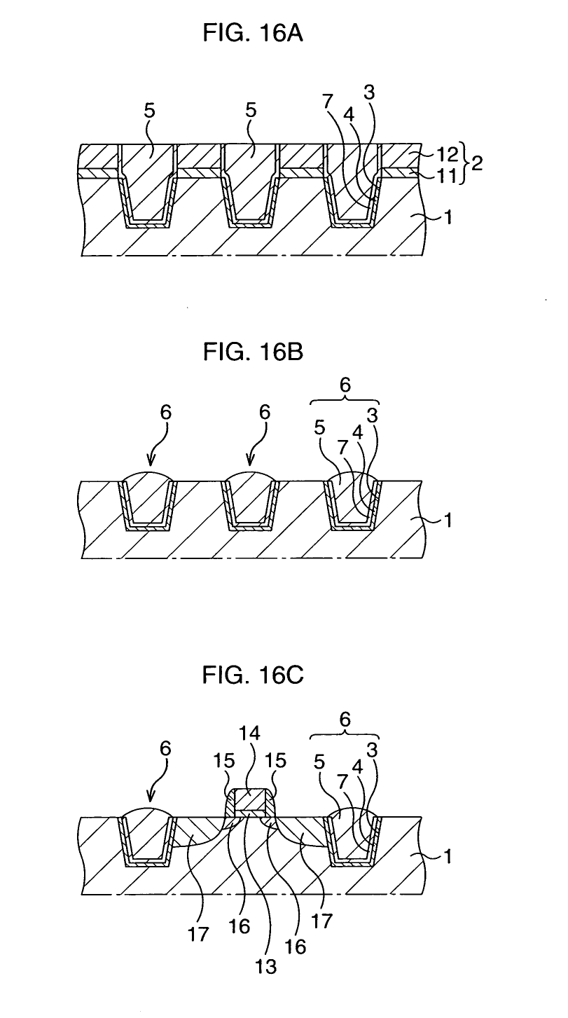

FIGS. 15A to 15E and FIGS. 16A to 16C are schematic sectional views sequentially showing process steps of fabricating a semiconductor device according to a modified example of the fourth embodiment.

First, as shown in FIGS. 15A to 15D, the nitride film liner 7 is formed on the inner wall surface of the isolation trenches 3 while placing thermal oxide film 4 thereunder, by the processes similar to those shown in FIGS. 13A to 13D in the fourth embodiment.

Next, as shown in FIG. 15E, the nitride film liner 7 is subjected to plasma treatment.

In further detail, using a plasma treatment apparatus, nitrogen gas or a nitrogen-containing gas (a mixed gas of nitrogen and a carrier gas such as argon gas) is introduced therein, so as to condition a nitrogen atmosphere as having a pressure of 667 Pa (5 Torr), a plasma is then excited therein typically at 400° C., and the nitride film liner 7 is exposed to the plasma. By the plasma treatment, at least the surficial portion of the nitride film liner 7 is modified to have a further complete and uniform state of nitriding.

Thereafter, as shown in FIGS. 16A to 16C, by the process steps similar to those shown in FIGS. 14A to 14C in the fourth embodiment, a semiconductor device is completed as having the element active regions zoned by the element isolation structures 6 on the silicon semiconductor substrate 1, and as having the MOS transistor 10 formed in the element active region.

In the process of filling the isolation trenches 3 with the buried insulating film 5 shown in FIG. 16B, deposition of the HDP-SiO film on the nitride film liner 7, without being annealed as in the conventional process, results in etching of the nitride film liner 7 at the center portion of the silicon semiconductor substrate 1, due to a plasma excited for growth of the HDP-SiO film.

In contrast in this embodiment, the surficial portion of the nitride film liner 7 is modified to have a further complete and uniform state of nitriding, so that the surficial portion can function as an etching protecting film, and thereby etching of the nitride film liner 7 is avoidable. Moreover, the surficial portion is composed of the nitride film liner 7 further completely nitrided, so that size of the opening of the isolation trenches 3 is kept almost unchanged, raising no fear of narrowing of the opening.

As has been described in the above, this embodiment can prevent the nitride film liner 7 from being unnecessarily etched off during formation of the buried insulating film 5, and can obtain stable and uniform element isolation characteristics, without forming any oxide film liner or the like on the inner wall surface of the isolation trenches 3 (and consequently without making it difficult to completely fill the isolation trenches 3 with the buried insulating film 5, due to narrowed size of opening of the isolation trenches 3), and can therefore realize a semiconductor device having the highly-reliable element isolation structures 6 capable of ensuring excellent element isolation characteristics, even when applied to large-diameter semiconductor substrates.

The present invention can obtain stable and uniform element isolation characteristics without forming the oxide film liner or the like on the inner wall surface of the isolation trench, and to ensure a sufficient level of adhesiveness of the insulating material filled in the isolation trench, and can therefore realize a semiconductor device having a highly-reliable element isolation structure capable of ensuring uniform and excellent element isolation characteristics, and a uniform and sufficient level of adhesiveness of the buried insulating material, even when applied to large-diameter semiconductor substrates.

What is claimed is:

1. A method of fabricating a semiconductor device comprising:
forming a trench in a device isolation region of a semiconductor substrate;
thermally oxidizing the inner wall surface of said trench;
annealing said inner wall surface; and
filling said trench with at least an insulating material.

2. The method of fabricating a semiconductor device according to claim 1, wherein said annealing is carried out for each of said semiconductor substrate using a single-wafer-type annealing apparatus.

3. The method of fabricating a semiconductor device according to claim 2, wherein said heating apparatus is a lamp annealer.

4. The method of fabricating a semiconductor device according to claim 1, wherein said annealing is carried out using a batch-type annealing furnace.

5. The method of fabricating a semiconductor device according to claim 1, wherein said annealing is carried out with an oxygen gas or an oxygen-containing gas.

6. The method of fabricating a semiconductor device according to claim 1, wherein said annealing is carried with a nitrogen gas or a nitrogen-containing gas.

7. The method of fabricating a semiconductor device according to claim 1, further comprising, posterior to said annealing and prior to said thermal oxidation of said inner wall surface, forming a nitride film so as to cover said inner wall surface.

8. The method of fabricating a semiconductor device according to claim 1, wherein said insulating material is an insulating material obtained by high-density plasma process.

9. A method of fabricating a semiconductor device comprising:
forming a trench in a device isolation region of a semiconductor substrate;
thermally oxidizing the inner wall surface of said trench;
subjecting the inner wall surface of said trench to plasma treatment; and
filling said trench with at least an insulating material.

10. The method of fabricating a semiconductor device according to claim 9, wherein said plasma treatment is carried out with an oxygen gas or an oxygen-containing gas.

11. The method of fabricating a semiconductor device according to claim 9, wherein said annealing is carried out with a nitrogen gas or a nitrogen-containing gas.

12. The method of fabricating a semiconductor device according to claim 9, further comprising, posterior to said annealing of said inner wall surface and prior to said thermal oxidation, forming a nitride film so as to cover said inner wall surface.

13. The method of fabricating a semiconductor device according to claim 9, wherein said insulating material is an insulating material obtained by high-density plasma process.

14. A semiconductor device comprising:
a semiconductor substrate; and
an element isolation structure having, as being formed in a device isolation region of said semiconductor substrate, a trench filled with at least an insulating material;
wherein said element isolation structure has an oxide film formed by thermal oxidation of the inner wall surface of said trench, and has a nitride film formed by thermally nitriding or by plasma-nitriding the surface of said oxide film.

15. A semiconductor device comprising:
a semiconductor substrate; and
an element isolation structure having, as formed in a device isolation region of said semiconductor substrate, a trench filled with at least an insulating material;
wherein said element isolation structure has a first oxide film formed by thermal oxidation of the inner wall surface of said trench, has a nitride film covering said inner wall surface while placing said first oxide film thereunder, and has a second oxide film formed by thermal oxidation of, or by plasma-oxidizing the surface of said nitride film.
